(19) United States
(12) Patent Application Publication
(10) Pub. No.: US 2016/0276617 A1
(43) Pub. Date: Sep. 22, 2016

(54) OPPOSED SUBSTRATE OF AN OLED ARRAY SUBSTRATE AND METHOD FOR PREPARING THE SAME, AND DISPLAY DEVICE

(71) Applicant: BOE TECHNOLOGY GROUP CO., LTD., Beijing (CN)

(72) Inventors: Yonglian QI, Beijing (CN); Chuanxiang XU, Beijing (CN); Can WANG, Beijing (CN)

(73) Assignee: BOE TECHNOLOGY GROUP CO., LTD., Beijing (CN)

(21) Appl. No.: 14/407,009

(22) PCT Filed: Apr. 18, 2014
(86) PCT No.: PCT/CN2014/075684

§ 371 Date: Dec. 10, 2014

(30) Foreign Application Priority Data
Dec. 27, 2013 (CN) 201310743033.0

(51) Int. Cl. H01L 51/52; H01L 51/56; H01L 27/32

(52) U.S. Cl. CPC H01L 51/525; H01L 51/5284; H01L 27/322; H01L 51/56; H01L 27/3244

(57) ABSTRACT

The present relates to the field of display technologies and discloses an opposed substrate of an OLED array substrate and a method for preparing the same, and a display device. In the embodiments of the invention, the layer structure of the opposed substrate of an OLED array substrate can be simplified, and the preparation difficulty of the opposed substrate can be lowered, thereby the yield rate of the opposed substrate can be improved. The opposed substrate of an OLED array substrate comprises a planarization layer and a plurality of protrusions located on the planarization layer, wherein, the planarization layer and the protrusions are conductive, and the protrusions are electrically connected with the electrodes of the OLED array substrate.

### CROSS-REFERENCE TO RELATED APPLICATION

This application is the U.S. national phase of PCT Application No. PCT/CN2014/075684 filed on Apr. 18, 2014, which claims priority to Chinese Patent Application No. 201310743033.0 filed on Dec. 27, 2013, the disclosure of which is incorporated in its entirety by reference herein.

### BACKGROUND OF THE INVENTION

1. Field of the Invention

The present invention relates to the field of display technologies, and in particular, to an opposed substrate of an OLED array substrate and a method for preparing the same, and a display device.

2. Description of the Prior Art

An Organic Light Emitting Diode (OLED) is an organic thin-film electroluminescent device, and it has the advantages of simple preparation process, low cost, high luminous efficiency, being easy to form a flexible structure, and wide visual angle, etc. The display technology that utilizes organic light emitting diodes has become an important display technology.

Usually, OLED display devices are divided into two types, i.e., bottom-emission OLED display device and top-emission OLED display device, wherein the array substrate of the top-emission OLED display device includes a metal anode, a metal cathode, and an organic layer located between the metal anode and the metal cathode, etc., wherein, the light emitted by the organic layer irradiates out of the array substrate from the side of the metal cathode.

In order to make the light irradiate out of the array substrate from the side of the metal cathode, the thickness of the metal cathode is usually only several nanometers, which causes that the resistance of the metal cathode large, more electric energy needs to be consumed when the metal cathode and the metal anode jointly drive the organic layer to emit light, more heat is generated, and the normal operation of the array substrate may be influenced easily.

In the prior art, in order to reduce the resistance of the metal cathode, the top-emission OLED display device further includes an opposed substrate of the array substrate (that is, a substrate arranged opposite to the array substrate). At present, the resistance of the metal cathode is reduced mainly by forming a planarized protection layer and a plurality of protrusions located on the planarized protection layer on an opposed substrate, forming a conducting layer on the planarized protection layer and the protrusions via sputtering, etc., and realizing the parallel connection between the conducting layer and the metal cathode by electrically connecting the conducting layer located on the protrusions with the metal cathode. During the implementation of the embodiments of the invention, the inventors find that in the prior art, as restrained by the manufacturing process, an unhealthy tendency tends to occur on the conducting layer located on the protrusions, for example, the conducting layer on the planarized protection layer is broken, thereby the structure of the opposed substrate will be complex, the processing cost will be high, and the product yield rate will be low.

### SUMMARY OF THE INVENTION

The technical problem to be solved by the embodiments of the invention is to provide an opposed substrate of an OLED array substrate and a method for preparing the same, and a display device, thereby the layer structure of the opposed substrate of an OLED array substrate can be simplified, and the preparation difficulty of the opposed substrate can be lowered, thereby the yield rate of the opposed substrate can be improved.

In order to solve technical problem, the embodiments of the invention employ the following technical solutions:

In the first aspect of embodiments of the invention, there provides an opposed substrate of an OLED array substrate, which comprises a planarization layer and a protrusion located on the planarization layer, wherein, the planarization layer and the protrusion are conductive, and the protrusion is electrically connected with an electrode of the OLED array substrate.

Further, the protrusion and the planarization layer are formed integrally.

Further, the opposed substrate further comprises a black matrix, wherein the planarization layer is located on the black matrix, and the planarization layer also functions as a color filter layer.

Futher, the opposed substrate further comprises a black matrix and a color filter layer, wherein, the color filter layer is located on the black matrix, and the planarization layer is located on the color filter layer.

Further, the protrusion is set corresponding to the black matrix.

Further, the material of the planarization layer and the protrusion is a transparent conductive resin.

In the technical solution of embodiment of the invention, because the planarization layer and the protrusion on the opposed substrate of an OLED array substrate are both conductive, after the opposed substrate and the array substrate are oppositely arranged to form a cell, each protrusion is electrically connected to an electrode of the OLED array substrate, which is equivalent to that the planarization layer is connected to the electrode of the OLED array substrate in parallel. Therefore, the resistance of the electrode of the OLED array substrate is reduced, and at the same time, no conducting layer needs to be formed for the opposed substrate thereof via sputtering, etc., thus the layer structure of the opposed substrate is simplified, the processing cost of the opposed substrate is lowered, and the product yield rate is improved.

In the second aspect of the embodiments of the invention, there provides a display device, which comprises an OLED array substrate and an opposed substrate of the above OLED array substrate.

In a third aspect of the embodiments of the invention, there provides a method for preparing an opposed substrate of an OLED array substrate, which comprises:

forming a conductive planarization layer on a base substrate; and

forming a conductive protrusion on the planarization layer, wherein the protrusion is configured for electrically connecting an electrode of the OLED array substrate.

Further, the step of forming a conductive planarization layer on a base substrate comprises:

forming a black matrix on a base substrate; and

forming a planarization layer, which also functions as a color filter layer, on the black matrix.

Further, the step of forming a conductive planarization layer on a base substrate comprises:

forming a black matrix on a base substrate;

forming a color filter layer on the black matrix; and

forming a planarization layer on the color filter layer.

Further, the protrusion is set corresponding to the black matrix.

Further, the protrusion and the planarization layer are formed integrally.

Further, the material of the planarization layer and the protrusion is a transparent conductive resin.

### BRIEF DESCRIPTION OF THE DRAWINGS

In order to more clearly illustrate the technical solutions of the embodiments of the invention or of the prior art, the drawings needed in the description of the embodiments will be briefly introduced below. Apparently, the drawings in the description below are only some embodiments of the invention, and other drawings may also be obtained by one of ordinary skills in the art according to these drawings without creative work.

FIG. 1 is structural representation 1 of an opposed substrate of an OLED array substrate according to one embodiment of the invention;

FIG. 2 is a schematic diagram showing the structure formed by oppositely arranging an OLED array substrate and an opposed substrate thereof to form a cell according to one embodiment of the invention;

FIG. 3 is structural representation 2 of an opposed substrate of an OLED array substrate according to one embodiment of the invention;

FIG. 4 is flow chart 1 showing the manufacturing of an opposed substrate of an OLED array substrate according to one embodiment of the invention;

FIG. 5 is flow chart 2 showing the manufacturing of an opposed substrate of an OLED array substrate according to one embodiment of the invention; and

FIG. 6 is flow chart 3 showing the manufacturing of an opposed substrate of an OLED array substrate according to one embodiment of the invention.

### DETAILED DESCRIPTION OF THE PREFERRED EMBODIMENTS

The technical solutions in the embodiments of the invention will be described clearly and fully below in conjunction with the drawings of the embodiments of the invention. Apparently, the embodiments described are only a part of the embodiments of the invention, rather than being the whole embodiments. All other embodiments made by one of ordinary skills in the art based on the embodiments in the invention without creative work pertain to the protection scope of the invention.

### Embodiment 1

This embodiment of the invention provides an opposed substrate of an OLED array substrate, as shown in FIG. 1, the OLED array substrate includes: a planarization layer 2 set on a first base substrate 1, and a plurality of protrusions 3 located on the planarization layer 2, wherein, the planarization layer 2 and the protrusions 3 are conductive, and the protrusions 3 are configured for electrically connecting an electrode of the OLED array substrate.

It should be noted that, a specific illustration will be given below by taking a metal cathode 10 of the OLED array substrate as an example.

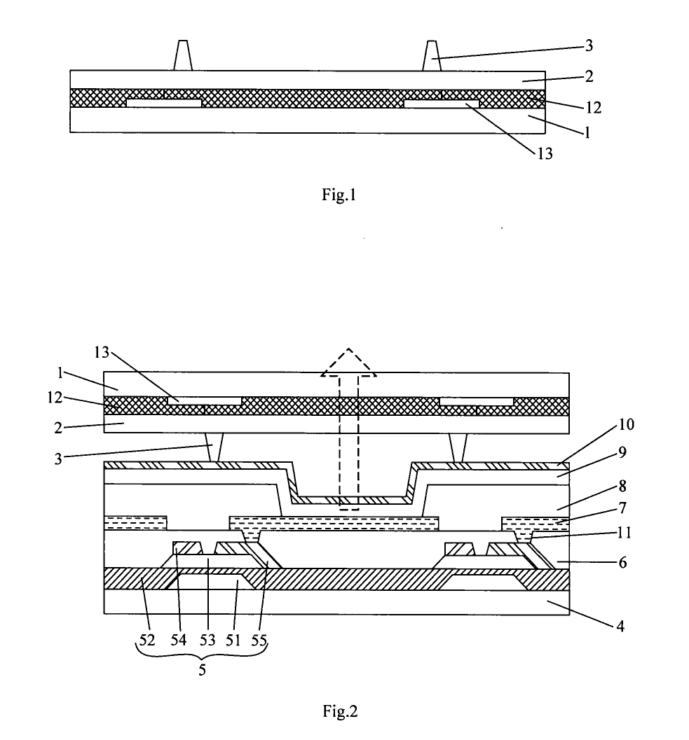

Specifically, as shown in FIG. 2, the OLED array substrate includes in turn, from bottom to top: a second base substrate 4, a thin-film transistor unit 5 located on the base substrate 4 of the array substrate, a passivation layer 6 located on the thin-film transistor unit 5, a pixel electrode 7 located on the passivation layer 6 and electrically connected with a drain electrode of the thin-film transistor unit 5, a pixel defining layer 8 that is set on the same layer as the pixel electrode 7 and isolates each pixel electrode 7, an organic layer 9 located on the pixel electrode 7 and the pixel defining layer 8, and a metal cathode 10 located on the organic layer 9.

Wherein, the OLED array substrate is a top-emission OLED array substrate, that is, as shown by the dotted arrow in FIG. 2, a light beam emitted by the organic layer 9 emerges from one side of the metal cathode 10. At this time, the thickness of the metal cathode 10 is usually very small, for example, only several nanometers, thus the resistance of the metal cathode 10 is large, more electric energy is needs to be consumed for driving the organic layer 9, and at the same time, because much heat will be generated due to the large resistance of the metal cathode 10, the normal operation of the OLED array substrate may be influenced.

Because the planarization layer 2 and the protrusions 3 are both conductive, as shown in FIG. 2, after the opposed substrate and the OLED array substrate are oppositely arranged to form a cell, each protrusion 3 is electrically connected to a metal cathode of the OLED array substrate, which is equivalent to that the planarization layer 2 is connected to the metal cathode of the OLED array substrate in parallel. Therefore, the resistance of the metal cathode of the OLED array substrate is reduced, and at the same time, no conducting layer needs to be formed for the opposed substrate thereof via sputtering, etc., thus the layer structure of the opposed substrate is simplified, the processing cost of the opposed substrate is lowered, and the product yield rate is improved.

Specifically, as shown in FIG. 2, an illustration will be given by taking a bottom-gate thin-film transistor as an example. The bottom-gate thin-film transistor unit 5 includes: a gate electrode 51 located on the second base substrate 4, a gate insulating layer 52 located on the gate electrode 51, an active layer 53 located on the gate insulating layer 52 and set corresponding to the gate electrode 51, and a source electrode 54 and a drain electrode 55 located on the active layer 53 and insulated from each other. Additionally, the gate line (not shown) of the array substrate may be located on the same pattern layer and formed in the same patterning process as the gate electrode 51; similarly, a data line (not shown) of the array substrate may be located on the same pattern layer and formed in the same patterning process as the source electrode 54 and the drain electrode 55.

It should be noted that, in the embodiments of the invention, the source electrode 54 and the drain electrode 55 are located on the same pattern layer and formed in the same patterning process, however, the source electrode 54 and the drain electrode 55 may also be set in different pattern layers and formed in one-time patterning process respectively, which will not be limited here.

It may be seen from FIG. 2 that a passivation layer 6 is covered on the thin-film transistor unit 5. By employing a passivation layer process, not only the harsh environment resistance of the display device can be enhanced, but also the photoelectric parameter performance of the thin-film transistor unit 5 may be improved. However, because the passivation layer 6 usually employs an insulating material such as silicon oxide, silicon nitride, hafnium oxide and resin, etc., in order to realize the electrical connection between the drain electrode 55 and the pixel electrode 7 that are isolated by the passivation layer 6, a via hole 11 is set correspondingly at a location corresponding to the drain electrode 55 of the thin-film transistor unit 5 in passivation layer 6, so that the pixel electrode 7 on the passivation layer 6 is electrically connected to the drain electrode 55 by the via hole 11. When the gate electrode 51 of the thin-film transistor unit 5 receives a signal transmitted through the gate line, a conducting channel of the active layer 53 is opened, the source electrode 54 and the drain electrode 55 of the thin-film transistor unit 5 are switch into conduction, and the data signal from the data line is transmitted from the source electrode 54 to the drain electrode 55, then transmitted from the drain electrode 55 to the pixel electrode 7 electrically connected therewith, and after the pixel electrode 7 obtains the data signal, a voltage difference exists between the pixel electrode 7 and the metal cathode 10, thus the organic layer 9 located between the pixel electrode 7 and the metal cathode 10 is made to emit light, and the light of the organic layer 9 irradiates out through the metal cathode 10.

Wherein, the pixel electrode 7 may be made of tin indium oxide (ITO) or a metal etc., for example, it may be made of a material such as silver-aluminum alloy and aluminum, etc.; however, it should be guaranteed that a matched work function exists between the pixel electrode 7 and the organic layer 9, so that the light emitted by the organic layer 9 can irradiate out basically from one side of the metal cathode 10, thereby the light utilization of a display device including the OLED array substrate and an opposed substrate thereof may be guaranteed, which will not be limited in the embodiments of the invention.

Although the invention has been illustrated by taking a bottom-gate thin-film transistor as an embodiment, the invention is not limited hereto; moreover, a top-gate thin-film transistor may be further used. In the embodiments of the invention, a bottom-gate thin-film transistor refers to a thin-film transistor in which the gate electrode of the thin-film transistor is located under the semiconductor layer of the thin-film transistor, and a top-gate thin-film transistor refers to a thin-film transistor in which the gate electrode of the thin-film transistor is located above the semiconductor layer of the thin-film transistor.

Further, the organic layer 9 specifically includes a hole transport layer, a light-emitting layer and an electron transport layer. When the voltage between the pixel electrode 7 and the metal cathode 10 is appropriate, the anode holes in the hole transport layer and the cathode charges in the electron transport layer will combine in the light-emitting layer, so that the light-emitting layer will generate a light.

It should be noted that, because an organic material which is suitable for transferring electrons, will not always be suitable for transferring holes, the electron transport layer and the hole transport layer of an organic light-emitting diode should select different organic materials or the same organic material doped with different impurities. At present, a material that is most often employed to manufacture a electron transport layer must have a high film-forming stability, a high thermal stability and a good electron transmissivity, and usually, a fluorescent dye compound is employed, for example, anthracene diazole-type derivative, naphthalene ring-containing derivative, 1-naphthyl-containing compound or derivative and 3-methylphenyl-containing compound or derivative, etc. However, the material of the hole transport layer belongs to aromatic amine fluorescent compounds, for example, an organic material such as 1-naphthyl-containing compound or derivative.

The material of the organic layer must have, in solid state, a strong fluorescence, a good carrier transporting performance, a good thermal stability and a good chemical stability, a high quantum efficiency and a vacuum depositability; for example, 8-hydroxyquinoline aluminum.

For example, the protrusions 3 and the planarization layer 2 are formed integrally. This not only may guarantee a stable connection between the protrusions 3 and the planarization layer 2, but also may eliminate a process for manufacturing the protrusions 3, thus the manufacturing cost of the opposed substrate may be further lowered.

Wherein, a typical material for the planarization layer 2 and the protrusions 3 is a transparent conductive resin. Specifically, the transparent conductive resin may be made by the following methods:

10˜50 parts by weight of translucent matrix resin and 1˜20 parts by weight of organic acid-doped polyaniline are added to 40˜90 parts by weight of toluene and stirred to dissolve completely, thereby forming the transparent conductive resin.

Or, 10˜50 parts by weight of translucent matrix resin, 1˜20 parts by weight of organic acid-doped polyaniline and 1˜15 parts by weight of crosslinking monomer are added to 40˜90 parts by weight of toluene and stirred to dissolve completely, thereby forming the transparent conductive resin.

Or, 10˜50 parts by weight of translucent matrix resin, 1˜20 parts by weight of organic acid-doped polyaniline, 1˜15 parts by weight of crosslinking monomer and 0.1˜1 parts by weight of curing initiator are added to 40˜90 parts by weight of toluene and stirred to dissolve completely, thereby forming the transparent conductive resin.

Additionally, nanometer-level antimony-doped SnO₂ and a macromolecular monomer, a dispersing agent and a surfactant, etc., may be mixed homogeneously to form a transparent conductive resin for manufacturing the planarized protection layer 3.

For example, nanometer-level conductive particles and a macromolecular monomer, a dispersing agent and a surfactant, etc., may be mixed homogeneously first, and then a transparent conductive resin for manufacturing the planarized protection layer 3 is formed by coating, depositing or the like method.

Wherein, in addition to nanometer-level antimony-doped SnO₂, nanometer-level tin indium oxide or nano silver, etc., may also be employed as the nanometer-level conductive particles.

In the embodiments of the invention, in order to make the thickness of a display panel formed after oppositely arranging an opposed substrate and an array substrate to form a cell meet the requirement, the height of the protrusions 3 in this embodiment is, for example, 2.0-5.0 μm.

Further, in the embodiments of the invention, for example, an organic layer 9 that can emit white light is used, thus a color filter layer 12 needs to be used in coordination to display a color display picture. At this time, as shown in FIG. 1 or FIG. 2, the opposed substrate of an OLED array substrate further includes a black matrix 13 and a color filter layer 12, wherein, the color filter layer 12 is located on the black matrix 13, and the planarization layer 2 is located on the color filter layer 12. In order to prevent that the protrusions 3 influence the aperture ratio of the opposed substrate, typically, the protrusions 3 is set corresponding to the black matrix 13, that is, any one of the protrusions 3 is set on a location corresponding to the black matrix 13.

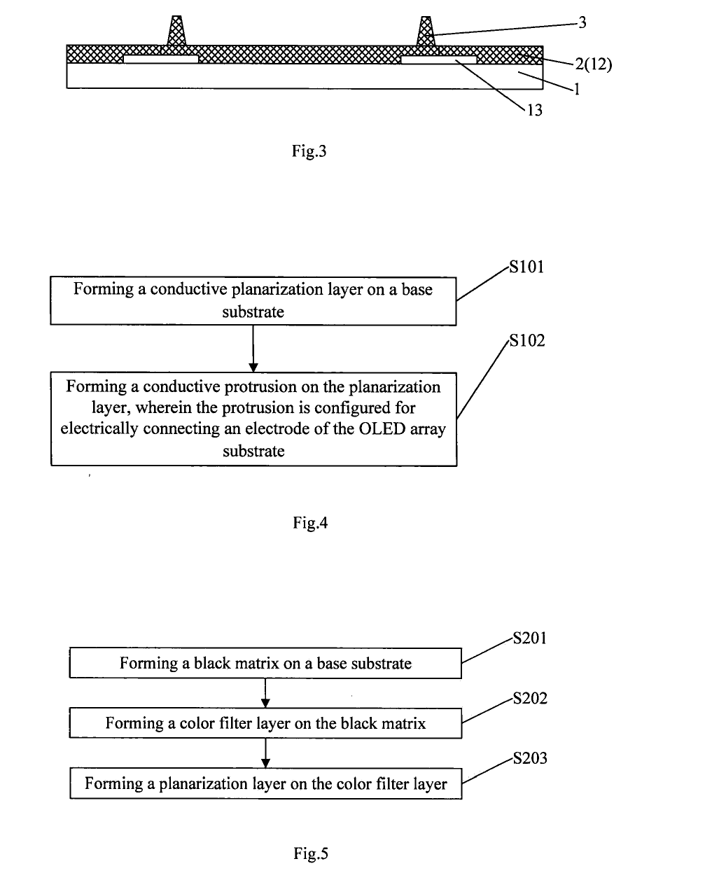

Or, as shown in FIG. 3, the opposed substrate further includes a black matrix 13, wherein the planarization layer 2 is located on the black matrix 13, and the planarization layer 2 also functions as a color filter layer 12. At this time, the planarization layer 2 has transmission regions of different colors, for example, a red transmission region, a blue transmission region and a green transmission region, wherein these three transmission regions are arranged according to a certain rule to form a planarization layer 2; as similar to the above, in order to prevent that the protrusions 3 influence the aperture ratio of the opposed substrate, the protrusions 3 are set corresponding to the black matrix 13.

Wherein, if the planarization layer 2 also functions as a color filter layer 12, during the manufacturing of the transparent conductive resin for forming the planarization layer 2, pigments of the corresponding colors further need to be mixed in to form a planarization layer 2 with transmission regions of different colors. At this time, the planarization layer 2 needs to be formed via multiple patterning processes and multiple mask plates, wherein, the number of the mask plates or the patterning processes needed is determined by the colors contained in the planarization layer 2.

It should be noted that, in the case that the protrusions 3 and the planarization layer 2 are formed integrally, if, as shown in FIG. 3, the planarization layer 2 also functions as a color filter layer 12, the protrusions 3 are formed at the same time a transmission region of a certain color of the planarization layer 2 is manufactured, that is, at the same time a transmission region of the color is formed. For example, when the protrusions 3 and the red transmission region of the planarization layer 2 are formed integrally, the protrusions 3 will also be red.

Further, one embodiment of the invention further provides a display device, which includes an OLED array substrate and an opposed substrate of the OLED array substrate. The display device may be a product or a component that has a display function, for example, mobile phone, tablet computer, TV set, display, notebook computer, digital photo frame and navigator, etc.

### Embodiment 2

Corresponding to Embodiment 1, this embodiment of the invention provides a method for preparing an opposed substrate of an OLED array substrate as disclosed in Embodiment 1. As shown in FIG. 4, the method includes:

Step S101: forming a conductive planarization layer on a base substrate; and

Step S102: forming a conductive protrusion on the planarization layer, wherein the protrusion is configured for electrically connecting an electrode of the OLED array substrate.

Further, as shown in FIG. 1, when the opposed substrate further includes a color filter layer 12 and a black matrix 13, Step S101 specifically includes, as shown in FIG. 5:

Step S201: forming a black matrix on a base substrate;

Step S202: forming a color filter layer on the black matrix; and

Step S203: forming a planarization layer on the color filter layer.

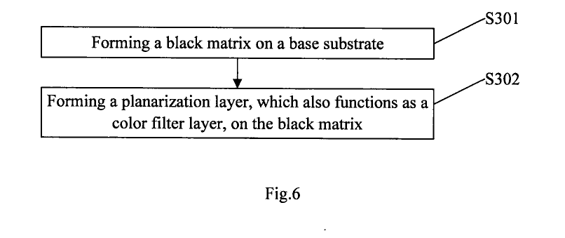

Or, as shown in FIG. 3, when the planarization layer 2 also functions as a color filter layer 12, Step S101 specifically includes, as shown in FIG. 6:

Step S301: forming a black matrix on a base substrate; and

Step S302: forming a planarization layer, which also functions as a color filter layer, on the black matrix.

Thereafter, as shown in FIG. 1, FIG. 2 or FIG. 3, the protrusions 3 should be set corresponding to the black matrix 13 to guarantee an aperture ratio of the opposed substrate.

Wherein, typically, the protrusions 3 and the planarization layer 2 are formed integrally.

The planarization layer 2 and the protrusions 3 should have a good transmittance. Therefore, the material of the planarization layer and the protrusions should be, for example, a transparent conductive resin.

The above description only shows some specific embodiments of the invention, and the protection scope of the invention is not limited thereto. Any variation or substitution made by one skilled in the art without departing from the technical scope of the invention should be contemplated by the protection scope of the invention. Therefore, the protection scope of the invention should be defined by the protection scope of the appended claims.

1. An opposed substrate of an OLED array substrate, comprising a planarization layer and a plurality of protrusions located on the planarization layer, wherein, the planarization layer and the protrusions are conductive, and the protrusions are electrically connected with electrodes of the OLED array substrate.

2. The opposed substrate according to claim 1, wherein, the protrusions and the planarization layer are formed integrally.

3. The opposed substrate according to claim 1, further comprising a black matrix, wherein the planarization layer is located on the black matrix, and the planarization layer also functions as a color filter layer.

4. The opposed substrate according to claim 1, further comprising a black matrix and a color filter layer, wherein, the color filter layer is located on the black matrix, and the planarization layer is located on the color filter layer.

5. The opposed substrate according to claim 3, wherein, the protrusions are set corresponding to the black matrix.

6. The opposed substrate according to claim 1, wherein, the material of the planarization layer and the protrusions is a transparent conductive resin.

7. A display device, comprising an OLED array substrate and the opposed substrate of an OLED array substrate according to claim 1.

8. A method for preparing an opposed substrate of an OLED array substrate, comprising:
forming a conductive planarization layer on a base substrate; and
forming a conductive protrusion on the planarization layer, wherein the protrusion is configured for electrically connecting an electrode of the OLED array substrate.

9. The preparation method according to claim 8, wherein, the step of forming a conductive planarization layer on a base substrate comprises:
forming a black matrix on a base substrate; and
forming a planarization layer, which also functions as a color filter layer, on the black matrix.

10. The preparation method according to claim 8, wherein, the step of forming a conductive planarization layer on a base substrate comprises:
forming a black matrix on a base substrate;
forming a color filter layer on the black matrix; and
forming a planarization layer on the color filter layer.

11. The preparation method according to claim 9, wherein, the protrusion is set corresponding to the black matrix.

12. The preparation method according to claim 8, wherein, the protrusion and the planarization layer are formed integrally.

13. The preparation method according to claim 8, wherein, the material of the planarization layer and the protrusion is a transparent conductive resin.

14. The opposed substrate according to claim 2, further comprising a black matrix, wherein the planarization layer is located on the black matrix, and the planarization layer also functions as a color filter layer.

15. The opposed substrate according to claim 2, further comprising a black matrix and a color filter layer, wherein, the color filter layer is located on the black matrix, and the planarization layer is located on the color filter layer.

16. The opposed substrate according to claim 14, wherein, the protrusions are set corresponding to the black matrix.

17. The opposed substrate according to claim 4, wherein, the protrusions are set corresponding to the black matrix.

18. The opposed substrate according to claim 15, wherein, the protrusions are set corresponding to the black matrix.

19. The preparation method according to claim 10, wherein, the protrusion is set corresponding to the black matrix.
